(19) United States
(12) Patent Application Publication
(10) Pub. No.: US 2009/0011606 A1
(43) Pub. Date: Jan. 8, 2009

(54) Substrate Processing Apparatus and Semiconductor Device Producing Method

(75) Inventor: Kenji Shinozaki, Toyama (JP)

Correspondence Address: BIRCH STEWART KOLASCH & BIRCH, PO BOX 747, FALLS CHURCH, VA, 22040-0747, US

(73) Assignee: Hitachi Kokusai Electric Inc., Tokyo (JP)

(21) Appl. No.: 10/577,043

(22) PCT Filed: Feb. 28, 2005
(86) PCT No.: PCT/JP05/03279

§ 371 Date: Jun. 25, 2007

(30) Foreign Application Priority Data
Mar. 1, 2004 (JP) 2004-056363

(51) Int. Cl. H01L 21/30; C23C 16/52

(52) U.S. Cl. 438/758; 118/719; 118/708; 257/E21.211

(57) ABSTRACT

A substrate processing apparatus, comprising: a processing chamber which provides a space for flowing desired gas and for depositing a desired film on a substrate; a lamp unit group having at least one lamp unit which is disposed in the processing chamber and which includes a filament for heating the substrate and a lamp tube surrounding the filament; at least first and second casings which surround the lamp unit, the first casing surrounding the lamp unit and the second casing surrounding the first casing; and a refrigerant flowing apparatus for flowing cooling medium to a first space formed between the lamp unit and the first casing, and to a second space formed between the first casing and the second casing, is disclosed.

### TECHNICAL FIELD

The present invention relates to a substrate processing apparatus and a producing method of a semiconductor device, and more particularly, to a substrate processing apparatus which flows desired gas to a semiconductor substrate to deposit a desired film on the substrate, and to a producing method of a semiconductor device using the substrate processing apparatus.

### BACKGROUND ART

As a substrate processing apparatus of this kind, there exists an apparatus which heats a substrate using a lamp. The present inventor devised that such an apparatus has a tube, an atmosphere in the tube is isolated from an atmosphere in a processing chamber which processes a substrate, a lamp is provided in the tube, and cooling medium is allowed to flow between the tube and the lamp (see Japanese Patent Application No. 2003-332277).

### DISCLOSURE OF THE INVENTION

The present inventor, however, further conducted research and as a result, the inventor found that the apparatus proposed by the inventor has a problem that gas flowing in the processing chamber reacted when a substrate was processed and deposition was produced on an outer side of the tube.

Hence, it is a main object of the present invention to provide a substrate processing apparatus in which desired gas is allowed to flow over a substrate, the substrate is heated by a lamp and a desired film is deposited on the substrate, and it is possible to restrain or prevent a deposition from being generated on a casing such as a tube which covers a lamp. It is also an object of the invention to provide a producing method of a semiconductor device using the substrate processing apparatus.

According to one aspect of the present invention, there is provided a substrate processing apparatus, comprising:

a processing chamber which provides a space for flowing desired gas and for depositing a desired film on a substrate;

a lamp unit group having at least one lamp unit which is disposed in the processing chamber and which includes a filament for heating the substrate and a lamp tube surrounding the filament;

at least first and second casings which surround the lamp unit, the first casing surrounding the lamp unit and the second casing surrounding the first casing; and

a refrigerant flowing apparatus for flowing cooling medium to a first space formed between the lamp unit and the first casing, and to a second space formed between the first casing and the second casing.

According to another aspect of the present invention, there is provided a producing method of a semiconductor device, comprising a step of,

using a substrate processing apparatus, comprising:

a processing chamber which provides a space for flowing desired gas and for depositing a desired film on a substrate;

a lamp unit group having at least one lamp unit which is disposed in the processing chamber and which includes a filament for heating the substrate and a lamp tube surrounding the filament;

at least first and second casings which surround the lamp unit, the first casing surrounding the lamp unit and the second casing surrounding the first casing; and

a refrigerant flowing apparatus for flowing cooling medium to a first space formed between the lamp unit and the first casing, and to a second space formed between the first casing and the second casing,

depositing a desired film on the substrate.

### BRIEF DESCRIPTION OF THE FIGURES IN THE DRAWINGS

FIG. 1 is a schematic plan view used for explaining a processing furnace of a substrate processing apparatus according to an embodiment 1 of the present invention.

FIG. 2 is a vertical sectional view taken along the line A-A in FIG. 1.

FIG. 3 is a schematic perspective view used for explaining a chamber-penetrating quartz tube used in the embodiment 1 of the present invention.

FIG. 4 is a diagram showing a relation between a temperature of a bulb of the lamp and a relative lifetime of the lamp.

FIG. 5 is a diagram showing variation with time of volume of cooling air by an air cooling gas blower.

FIG. 6 is a schematic transversal sectional view for explaining a substrate processing apparatus to which the present invention is preferably applied.

### PREFERABLE MODE FOR CARRYING OUT THE INVENTION

According to one preferable aspect of the present invention, there is provided a substrate processing apparatus, comprising:

a processing chamber which provides a space for flowing desired gas and for depositing a desired film on a substrate;

a lamp unit group having at least one lamp unit which is disposed in the processing chamber and which includes a filament for heating the substrate and a lamp tube surrounding the filament;

at least first and second casings which surround the lamp unit, the first casing surrounding the lamp unit and the second casing surrounding the first casing; and

a refrigerant flowing apparatus for flowing cooling medium to a first space formed between the lamp unit and the first casing, and to a second space formed between the first casing and the second casing.

Preferably, the substrate processing apparatus includes a controller which controls the refrigerant flowing apparatus such that an amount of cooling medium allowed to flow into the second space is greater than an amount of cooling medium allowed to flow into the first space at least while the substrate is being processed in the processing chamber.

Preferably, the substrate processing apparatus includes a controller which controls amounts of cooling medium flowing into the first and second spaces such that a temperature of the first casing is lower than a temperature of the second casing at least while the substrate is being processed in the processing chamber.

Preferably, different cooling mediums are respectively flowed into the first space and the second space at least while the substrate is being processed in the processing chamber, and a cooling efficiency of the cooling medium flowing into the second space is higher than a cooling efficiency of the cooling medium flowing into the first space. For example, N₂ flows into the first space, and He of H₂ flows into the second space.

Preferably, the substrate processing apparatus includes a controller which controls the refrigerant flowing apparatus such that the flow rate of the cooling medium is greater in a process in which a temperature of the substrate located in the processing chamber is increased than in a process in which the temperature of the substrate is lowered.

Preferably, at least one of the first space and the second space is provided with temperature detection means, and a flow rate of cooling medium flowing into at least one of the first space and the second space is controlled based on a result of detection of the temperature detection means. More preferably, both of the first space and second space are provided with temperature detection means, respectively, and flow rates of cooling mediums flowing into the first space and the second space are controlled respectively based on results of detections of the temperature detection means.

According to another preferable aspect of the present invention, there is provided a producing method of a semiconductor device for producing a semiconductor device using the above-mentioned substrate processing apparatus.

Next, a preferred embodiment of the present invention will be explained with reference to the drawings.

### EMBODIMENT 1

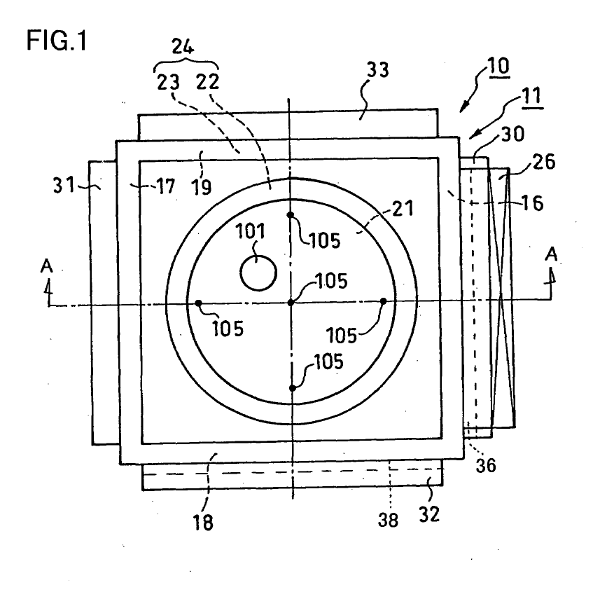

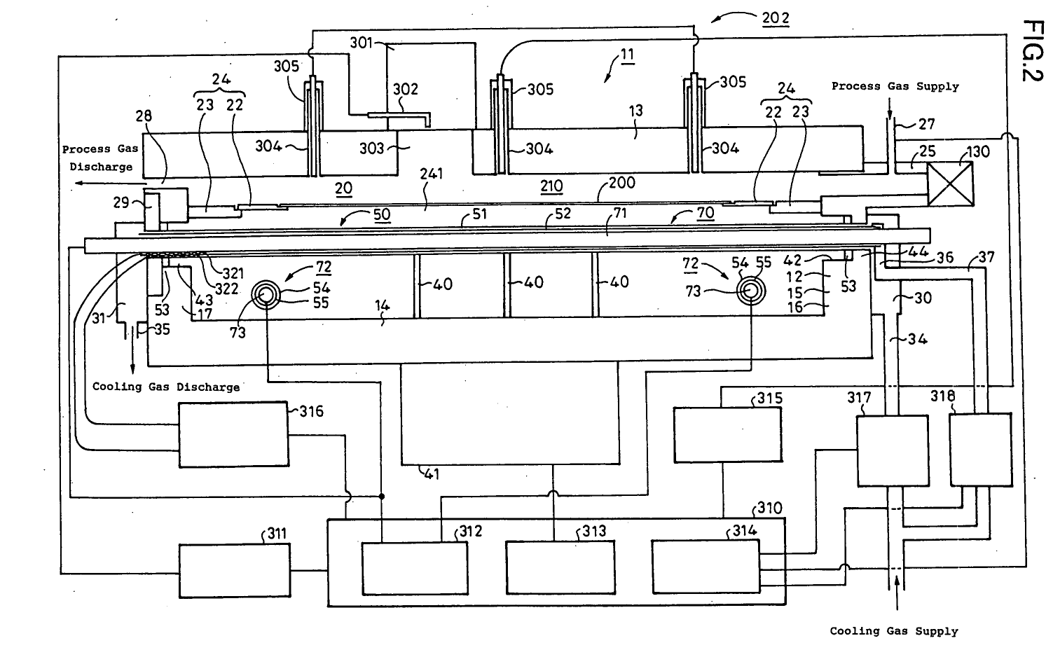

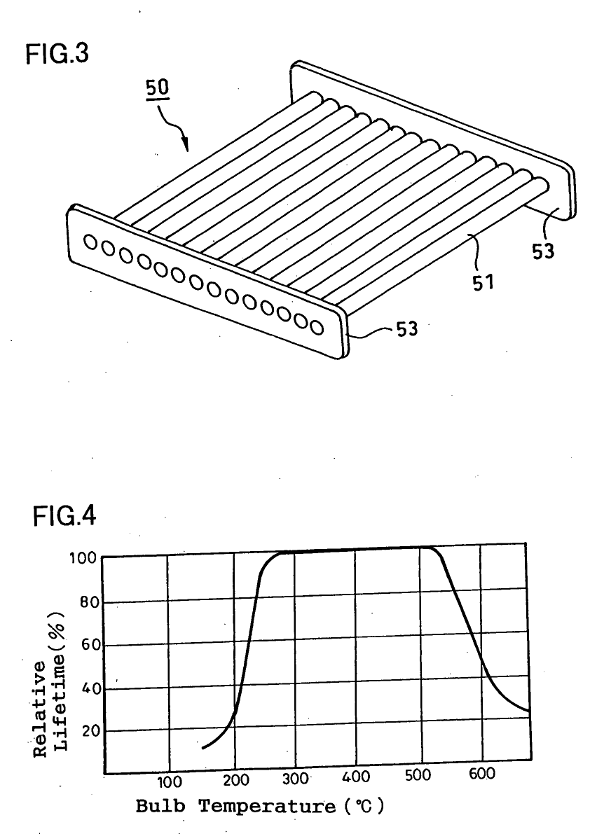

FIG. 1 is a schematic plan view used for explaining a processing furnace of a substrate processing apparatus according to an embodiment 1 of the present invention. FIG. 2 is a vertical sectional view taken along the line A-A in FIG. 1. FIG. 3 is a schematic perspective view used for explaining a chamber-penetrating quartz tube used in the embodiment 1 of the invention.

Referring to FIGS. 1 and 2, a processing furnace 202 includes a chamber 11, a susceptor 24, and a heater assembly comprising an upper lamp group 70 and a lower lamp group 72. The chamber 11 includes a chamber lid 13 and a chamber main body 12. The chamber main body 12 includes a chamber sidewall 15 and a chamber bottom 14. The chamber sidewall 15 comprises four chamber sidewalls 16, 17, 18 and 19. A wafer 200 is a substrate to be processed. The wafer 200 is loaded on the susceptor 24 and processed. The susceptor 24 comprises a susceptor 23 and a susceptor 22 located inside of the susceptor 23. A through hole 241 is provided at an inner side of the susceptor 22. The through hole 241 is slightly smaller than the wafer 200. The susceptor 22 holds a periphery of the wafer 200. In a state where the wafer 200 is loaded on the susceptor 24, a processing chamber 20 is defined by the wafer 200, the susceptor 24, the chamber lid 13 and the chamber sidewalls 16, 17, 18 and 19. The chamber lid 13 and the chamber main body 12 constitute a processing chamber 210.

A flange 25 is mounted on the chamber sidewall 16 of the chamber 11. A gate valve 130 is mounted on a side end of the flange 25. The flange 25 is provided at its ceiling with a process gas supply tube 27 so that process gas can be supplied to the processing chamber 210. The process gas is discharged out from the processing chamber 210 through a process gas exhaust port 28 provided in a chamber sidewall 17. The wafer 200 is brought into the processing chamber 210 through the gate valve 130, and the wafer 200 is placed on the susceptor 22 by vertically moving the push-up pins 40. The wafer 200 which has been processed is brought up from the susceptor 22 by the push-up pins 40, and is brought out from the processing chamber 210 through the gate valve 130. The push-up pins 40 are vertically moved by a push-up pin vertically moving mechanism 41.

As shown in FIG. 3, concerning the upper lamp group 70, a plurality of quartz tubes 51 are arranged, flanges 53 are welded to both ends of the quartz tubes 51, respectively thereby forming a chamber-penetrating quartz tube 50, and the chamber-penetrating quartz tube 50 is mounted on the chamber 11. Gaps are provided between adjacent quartz tubes 51. A space between adjacent quartz tubes 51 where the push-up pin 40 exists is set wide so that the push-up pin 40 can move between the quartz tubes 51. The chamber-penetrating quartz tube 50 is inserted from a through hole 43 provided in the sidewall 17 of the rear portion of the chamber (on the opposite side from the gate valve 130), a tip end of the chamber-penetrating quartz tube 50 is inserted into a through hole 42 formed in the chamber sidewall 16, and a flange 53 on the tip end of the chamber-penetrating quartz tube 50 is pushed against a flange 44 provided on the chamber sidewall 16 through an O-ring (not shown). The flange 53 on the rear end of the chamber-penetrating quartz tube 50 is pushed by a chamber-penetrating quartz tube press flange 29 through an O-ring (not shown), and is fixed while pressing the front and rear two O-rings (not shown) of the chamber-penetrating quartz tube 50. Since the spaces between the both ends of the chamber-penetrating quartz tube 50 and the chamber 11 are sealed by the O-rings, an atmosphere in the processing chamber 210 and an atmosphere in the chamber-penetrating quartz tube 50 can be isolated from each other. As a result, the processing chamber 210 can be decompressed, and air-cooling gas can be allowed to flow into the chamber-penetrating quartz tube 50 as cooling medium.

Chamber-penetrating quartz tubes 52 are respectively inserted into the plurality of quartz tubes 51 of the chamber-penetrating quartz tube 50. Lamps 71 are inserted into the chamber-penetrating quartz tubes 52, respectively. Each lamp 71 comprises a lamp unit including a filament (not shown) and a lamp tube (not shown) surrounding the filament. Air cooling gas flows through an outside air cooling gas supply tube 34 by an outside air cooling gas blower 317, flows through an outside air cooling gas supply chamber 30, and flows into a space between the quartz tube 51 of the outer chamber-penetrating quartz tube 50 and the inner chamber-penetrating quartz tube 52, and passes through the outer quartz tube 51 and the inner chamber-penetrating quartz tube 52 and flows out into a chamber 31 and then, the air cooling gas is discharged from an air cooling gas exhaust port 35.

Further, air cooling gas flows through an inside air cooling gas supply tube 37 by an inside air cooling gas blower 318, flows through an inside air cooling gas supply chamber 36 provided in the outside air cooling gas supply chamber 30, and flows into a space between the lamp 71 and the inner chamber-penetrating quartz tube 52, passes between the lamp 71 and the inner chamber-penetrating quartz tube 52, flows out into the chamber 31 and then is discharged out from the air cooling gas exhaust port 35.

A flow rate of air cooling gas flowing through a space between the outer quartz tube 51 and the inner chamber-penetrating quartz tube 52, and a flow rate of air cooling gas flowing through a space between the lamp 71 and the inner chamber-penetrating quartz tube 52 are independently controlled by the outside air cooling gas blower 317 and the inside air cooling gas blower 318.

A thermocouple 321 is inserted between the outer quartz tube 51 and the inner chamber-penetrating quartz tube 52, and a thermocouple 322 is inserted between the inner chamber-penetrating quartz tube 52 and the lamp 71. Signals from the thermocouples 321 and 322 are sent to the temperature detector 316, temperatures are obtained there, and they are sent to a main controller 310. A gas controller 314 in the main controller 310 controls the outside air cooling gas blower 317 and the inside air cooling gas blower 318 in accordance with the obtained temperatures. The gas controller 314 also controls supply of process gas.

Concerning the lamp 71, a bulb portion except an end (sealed portion) thereof is an air cooled region where the volume of air can be varied. The end (sealed portion) of the lamp 71 is air cooled by another means (not shown).

Concerning the lower lamp group 72, a chamber-penetrating quartz tube 54 formed of quartz tube penetrates the chamber 11. Spaces between both ends of the chamber-penetrating quartz tube 54 and the sidewalls 18 and 19 of the chamber 11 are sealed by O-rings (not shown), respectively. An atmosphere in the processing chamber 210 and an atmosphere in the chamber-penetrating quartz tube 54 can be isolated from each other. As a result, the processing chamber 210 can be decompressed, and air cooling gas as cooling medium can be allowed to flow into the chamber-penetrating quartz tube 54.

A chamber-penetrating quartz tube 55 is inserted into the chamber-penetrating quartz tube 54. A lamp 73 is inserted into the chamber-penetrating quartz tube 55. The lamp 73 comprises a lamp unit having a filament (not shown) and a lamp tube (not shown) surrounding the filament. Air cooling gas flows in between the outer chamber-penetrating quartz tube 54 and the inner chamber-penetrating quartz tube 55 through the outside air cooling gas supply chamber 32 by the outside air cooling gas blower (not shown), passed between the outer chamber-penetrating quartz tube 54 and the inner chamber-penetrating quartz tube 55, flows out into the chamber 33 and then, is discharged out.

Air cooling gas flows in between the lamp 73 and the inner chamber-penetrating quartz tube 55 through the inside air cooling gas supply chamber 38 provided in the outside air cooling gas supply chamber 32 by the inside air cooling gas blower (not shown), flows and into the chamber 33 through between the lamp 73 and the inner chamber-penetrating quartz tube 55 and then, is discharged out. A flow rate of air cooling gas flowing between the outer chamber-penetrating quartz tube 54 and the inner chamber-penetrating quartz tube 55, and a flow rate of air cooling gas flowing between the lamp 73 and the inner chamber-penetrating quartz tube 55 are independently controlled by the outside air cooling gas blower (not shown) and the inside air cooling gas blower (not shown), respectively.

A thermocouple (not shown) is inserted in between the outer chamber-penetrating quartz tube 54 and the inner chamber-penetrating quartz tube 55, and a thermocouple (not shown) is inserted between the inner chamber-penetrating quartz tube 52 and the lamp 71. Signals from the thermocouples (not shown) are sent to the temperature detector 316, temperatures are obtained there, and they are sent to the main controller 310. The gas controller 314 in the main controller 310 controls the outside air cooling gas blower (not shown) and the inside air cooling gas blower (not shown) in accordance with the obtained temperatures.

Concerning the lamp 73, a bulb portion except an end (sealed portion) thereof is an air cooled region where the volume of air can be varied. The end (sealed portion) of the lamp 73 is air cooled by another means (not shown).

The processing furnace 202 of the substrate processing apparatus according to this embodiment includes non-contact type emissivity measuring means for measuring emissivity of the wafer 200 and for calculating the emissivity. That is, an emissivity measuring unit 301 is provided on the chamber lid 13, and an emissivity measuring probe 302 is provided in the emissivity measuring unit 301. The chamber lid 13 is provided with a through hole 303 so that the emissivity measuring probe 302 can measure light from the wafer 200. A signal from the emissivity measuring probe 302 is sent to the emissivity detector 311, the emissivity is obtained there, and it is sent to the main controller 310.

The processing furnace 202 further includes a plurality of temperature measuring probes 305 which are temperature detection means. Preferably, the processing furnace 202 includes five probes 305 which are positioned for measuring temperatures of different portions of the wafer 200. With this, consistency of the temperature of the wafer 200 over its entire surface during the processing cycle is secured. The chamber lid 13 is provided with five through holes 304, tip ends of the temperature measuring probes 305 are respectively inserted into the through holes 304 so that the light from the wafer 200 can be measured by the temperature measuring probes 305. These temperature measuring probes 305 are fixed to the chamber lid 13 and always measure the light quantum density emitted from a device surface of the wafer 200 in all processing conditions. Based on the light quantum density measured by the probes 305, the temperature of the wafer is calculated by the temperature detector 315, it is corrected by emissivity by the main controller 310 and then, it is compared with a set temperature. As a result of comparison, the main controller 310 calculates all of deviations, and the main controller 310 controls the amount of electricity to be supplied to a plurality of zones of the upper lamp group 70 and the lower lamp group 72 which are heating means in the heater assembly through the heating controller 312. The main controller 310 further includes a drive controller 313 which controls the push-up pin vertically moving mechanism 41.

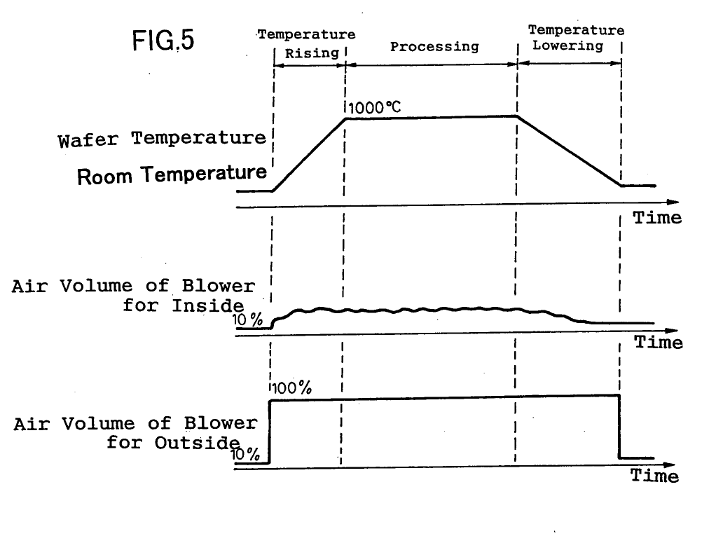

As shown in FIG. 4, in order to maintain the long lifetime of the lamp, it is necessary to maintain the bulb surface at 300° C. to 500° C. when the lamp stays on. On the other hand, in the case of CVD (Chemical Vapor Deposition) processing, in order to prevent gas (e.g., mono-silane, disilane, dichloro-silane) in the processing chamber from reacting with the quartz tube 51 of the outer chamber-penetrating quartz tube 50 of the upper lamp group 70 or the outer chamber-penetrating quartz tube 54 of the lower lamp group 72 and from being deposited, it is necessary to maintain the quartz tube 51 of the outer chamber-penetrating quartz tube 50 and the chamber-penetrating quartz tube 54 at about 200° or lower.

Hence, the gas controller 314 in the main controller 310 controls the outside air cooling gas blower 317 and the inside air cooling gas blower 318, thereby controlling a flow rate of air cooling gas flowing between the outer quartz tube 51 and the inner chamber-penetrating quartz tube 52 of the upper lamp group 70 and a flow rate of air cooling gas flowing between the lamp 71 and the inner chamber-penetrating quartz tube 52, and controlling the outside air cooling gas blower (not shown) and the inside air cooling gas blower (not shown), and the gas controller 314 controls a flow rate of air cooling gas flowing between the outer chamber-penetrating quartz tube 54 and the inner chamber-penetrating quartz tube 55 of the lower lamp group 72 and a flow rate of air cooling gas flowing between the lamp 73 and the inner chamber-penetrating quartz tube 55, maintains surfaces of bulbs of the lamps 71 and 73 at 300° C. to 500° C., e.g., 400° C., maintains the quartz tube 51 of the outer chamber-penetrating quartz tube 50 of the upper lamp group 70 and the outer chamber-penetrating quartz tube 54 of the lower lamp group 72 at 200° C. or lower, and prevents gas in the processing chamber from reacting with the quartz tube 51 of the outer chamber-penetrating quartz tube 50 or the outer chamber-penetrating quartz tube 54 and from being deposited.

This is shown in FIG. 5. The inside air cooling gas blower automatically adjusts the volume of cooling air so that the surfaces of bulbs of the lamps 71 and 73 are maintained at 400° C. In the outside air cooling gas blower, the volume of cooling air for preventing a film from being deposited is set to 100%.

As wafers become finer, a lamp heating apparatus as in this embodiment is required to rapidly rise or lower the temperature of the wafer 200. At that time, since the volume of cooling air for preventing a film from being deposited is set to 100% in the outside air cooling gas blower, it is possible to avoid a case in which the temperature of the bulb of the lamp and the temperature of the chamber-penetrating quartz tube are not lowered and stay high, and it is possible to rapidly lower the temperature of the wafer. In this case, when the temperature is lowered, if the volume of air of the inside air cooling gas blower is increased as compared with a case in which the temperature is being increased or a wafer is being processed, the temperature of the wafer can be lowered more rapidly.

It becomes unnecessary that the volume of air of the outside air cooling gas blower is 100% when the temperature is increased or a wafer is being processed and depending upon sizes of the outer quartz tube 51 and the inner chamber-penetrating quartz tube 52 of the upper lamp group 70 and the outer chamber-penetrating quartz tube 54 and the inner chamber-penetrating quartz tube 55 of the lower lamp group 72, and depending upon ability of air cooling gas supply of the outside air cooling gas blower and the inside air cooling gas blower. In such a case, if the volume of air of the outside air cooling gas blower during lowering of the temperature is set greater than that during the rising of temperature or during processing, the temperature of the wafer can rapidly be lowered. In this case also, if the volume of air of the inside air cooling gas blower when the temperature is lowered is set greater than that during the rising of temperature or during processing, the temperature of the wafer can be lowered more rapidly.

If this embodiment is carried out, it is possible to prevent the temperature of the chamber-penetrating quartz tube from increasing to high temperature, a case in which gas in the processing chamber reacts and is deposited on an outer side of the chamber-penetrating quartz tube can be restrained or prevented, and there is practically an extremely great effect on providing a substrate processing apparatus capable of rapidly rising a temperature of a wafer.

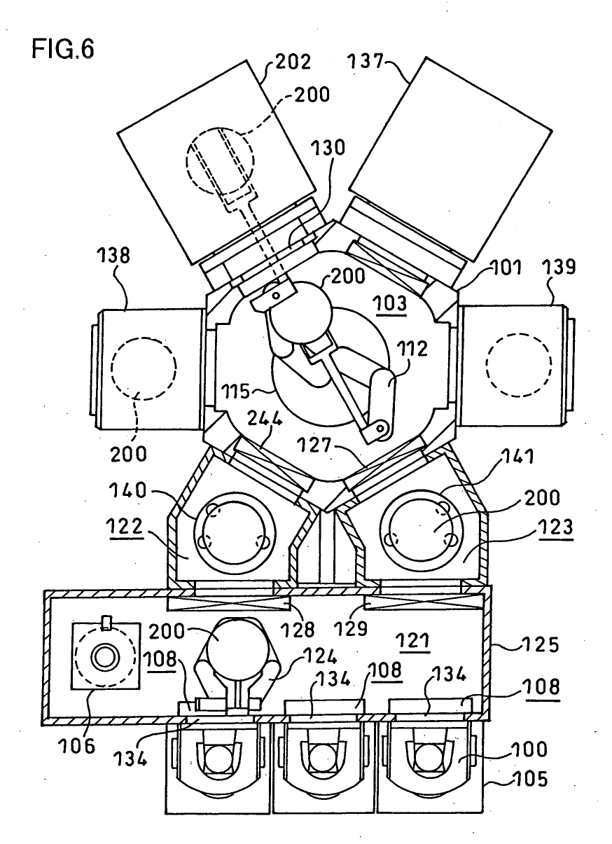

Next, an outline of the substrate processing apparatus to which the present invention is applied will be explained with reference to FIG. 6.

In the substrate processing apparatus to which the invention is suitably applied, an FOUP (front opening unified pod, and this will be referred to as pod, hereinafter) is used as a carrier which carries a substrate such as a wafer. In the following explanation, directions such as front, rear, right and left are referred to based on FIG. 6. That is, with respect to the paper sheet of FIG. 6, a front side is a lower side, a rear side is an upper side, and left and right sides are left and right sides with respect to the paper sheet of FIG. 6.

As shown in FIG. 6, the substrate processing apparatus includes a first transfer chamber 103. The first transfer chamber 103 is of a load lock chamber structure capable of withstanding pressure (negative pressure) less than atmospheric pressure such as vacuum state. The first transfer chamber 103 has a case 101. The case 101 is of hexagonal shape as viewed from above, and the case is formed into a box-like shape whose upper and lower ends are closed. A first wafer loader 112 for loading a wafer 200 under negative pressure is disposed in the first transfer chamber 103. The first wafer loader 112 can vertically be moved by an elevator 115 while maintaining air-tightness of the first transfer chamber 103.

The case 101 has six sidewalls. A bring-in preliminary chamber 122 and a bring-out preliminary chamber 123 are connected to two of the six sidewalls of the case 101 located on the front side respectively through gate valves 244 and 127. The preliminary chambers 122 and 123 are of load lock chamber structures capable of withstanding negative pressure. A bring-in substrate stage 140 is disposed in the preliminary chamber 122, and a bring-out substrate stage 141 is disposed in the preliminary chamber 123.

A second transfer chamber 121 is connected to front sides of the preliminary chamber 122 and the preliminary chamber 123 through gate valves 128 and 129. The second transfer chamber 121 is used under substantially atmospheric pressure. A second wafer loader 124 for loading the wafer 200 is disposed in the second transfer chamber 121. The second wafer loader 124 is vertically moved by an elevator 126 disposed in the second transfer chamber 121, and the second wafer loader 124 reciprocates in the lateral direction by a linear actuator 132.

As shown in FIG. 6, an orientation flat aligning apparatus 106 is disposed on the left side of the second transfer chamber 121.

As shown in FIG. 6, wafer IN/OUT openings 134 are disposed in a case 125 of the second transfer chamber 121. Each the wafer IN/OUT opening 134 brings the wafer 200 into and out from the second transfer chamber 121. Lids 142 each closing the wafer IN/OUT opening, and pod openers 108 are also disposed in the case 125. The pod opener 108 includes a cap of a pod 100 placed on an IO STAGE 105, and a cap open/close mechanism 136 for opening and closing a lid 142 which closes the wafer IN/OUT opening 134. The cap of the pod 100 placed on the IO STAGE 105 and the lid 142 for closing the wafer IN/OUT opening 134 are opened and closed by the cap open/close mechanism 136. With this, the pod 100 can brings the wafer in and out. The pod 100 is supplied to and discharged from the IO STAGE 105 by a transfer apparatus (RGV).

As shown in FIG. 6, a first processing furnace 202 and a second processing furnace 137 are adjacently connected to two back surface side sidewalls of the six sidewalls of the case 101. Wafers are subjected to desired processing by the first processing furnace 202 and the second processing furnace 137. The first processing furnace 202 and the second processing furnace 137 respectively comprise cold wall type processing furnaces. A first cleaning unit 138 as a third processing furnace and a second cleaning unit 139 as a fourth processing furnace are connected to the remaining two opposed sidewalls of the six sidewalls of the case 101. Each of the first cleaning unit 138 and the second cleaning unit 139 cools the processed wafer 200.

The processing procedure using the substrate processing apparatus having the structure will be explained below.

In a state where 25 wafers 200 which are not yet processed are accommodated in the pod 100, the wafers 200 are brought into the substrate processing apparatus which carries out the processing procedure by the transfer apparatus. As shown in FIG. 6, the pod 100 which was brought into the substrate processing apparatus is placed on the IO STAGE 105 from the transfer apparatus. The cap of the pod 100 and the lid 142 for opening and closing the wafer IN/OUT opening 134 are removed by the cap open/close mechanism 136, and a wafer access opening of the pod 100 is opened.

If the pod 100 is opened by the pod opener 108, the second wafer loader 124 disposed in the second transfer chamber 121 picks up the wafers 200 from the pod 100, transfers the wafers 200 into the preliminary chamber 122, and moves the wafers 200 to the substrate stage 140. During this moving operation, the gate valve 244 on the side of the first transfer chamber 103 is closed, and negative pressure in the first transfer chamber 103 is maintained. If the moving operation of the wafer 200 to the substrate stage 140 is completed, the gate valve 128 is closed, and the preliminary chamber 122 is evacuated into negative pressure by an exhaust apparatus (not shown).

If the preliminary chamber 122 is evacuated into a preset pressure, the gate valves 244 and 130 are opened, the preliminary chamber 122, the first transfer chamber 103 and the first processing furnace 202 are brought into communication with each other. Then, the first wafer loader 112 of the first transfer chamber 103 picks up the wafer 200 from the substrate stage 140 and brings the same into the first processing furnace 202. Then, process gas is supplied into the first processing furnace 202, and the wafer 200 is subjected to desired processing.

If the processing in the first processing furnace 202 is completed, the processed wafer 200 is transferred out into the first transfer chamber 103 by the first wafer loader 112 of the first transfer chamber 103.

Then, the first wafer loader 112 transfers, to the first cleaning unit 138, the wafer 200 which was transferred out from the first processing furnace 202, and cools the processed wafer.

If the wafer 200 is transferred to the first cleaning unit 138, the first wafer loader 112 transfers, into the first processing furnace 202 by the above-described operation, the wafer 200 which is previously prepared on the substrate stage 140 of the preliminary chamber 122, process gas is supplied into the first processing furnace 202, and the wafer 200 is subjected to desired processing.

If cooling time which is preset in the first cleaning unit 138 is elapsed, the cooled wafer 200 is transferred into the first transfer chamber 103 from the first cleaning unit 138 by the first wafer loader 112.

If the cooled wafer 200 is transferred into the first transfer chamber 103 from the first cleaning unit 138, the gate valve 127 is opened. The first wafer loader 112 transfers, into the preliminary chamber 123, the wafer 200 which was transferred out from the first cleaning unit 138, and places the same on the substrate stage 141. Then, the preliminary chamber 123 is closed by the gate valve 127.

If the preliminary chamber 123 is closed by the gate valve 127, the pressure in the exhaust preliminary chamber 123 is returned into substantially atmospheric pressure by inert gas. If the pressure in the preliminary chamber 123 is returned to the substantially atmospheric pressure, the gate valve 129 is opened, the lid 142 which closes the wafer IN/OUT opening 134 corresponding to the preliminary chamber 123 of the second transfer chamber 121 and the cap of the empty pod 100 placed on the IO STAGE 105 are opened by the pod opener 108. Then, second wafer loader 124 of the second transfer chamber 121 picks up the wafer 200 from the substrate stage 141 and brings the wafer 200 to the second transfer chamber 121, and accommodates the same in the pod 100 through the wafer IN/OUT opening 134 of the second transfer chamber 121. If the accommodating operation of the 25 processed wafers 200 in the pod 100 is completed, the cap of the pod 100 and the lid 142 which closes the wafer IN/OUT opening 134 are closed by the pod opener 108. The closed pod 100 is transferred to a next step from the IO STAGE 105 by the transfer apparatus.

By repeating the above-described operations, the wafers are sequentially processed. Although the first processing furnace 202 and the first cleaning unit 138 are used for the above operations, the same operations are also carried out using the second processing furnace 137 and the second cleaning unit 139.

In the substrate processing apparatus, although a wafer is brought into the preliminary chamber 122 and a wafer is brought out from the preliminary chamber 123, but a wafer may be brought into the preliminary chamber 123 and the wafer may be brought out from the preliminary chamber 122. The first processing furnace 202 and the second processing furnace 137 may carry out the same processing or different processing. When the first processing furnace 202 and the second processing furnace 137 carry out different processing, a wafer 200 may be subjected to a certain processing by the first processing furnace 202 and then may continuously be subjected to another processing by the second processing furnace 137. When the second processing furnace 137 carries out different processing after the wafer 200 is subjected to a certain processing by the second processing furnace 137, the wafer 200 may be transferred to the second processing furnace 137 through the first cleaning unit 138 (or second cleaning unit 139).

The entire disclosure of Japanese Patent Application No. 2004-56363 filed on Mar. 1, 2004 including specification, claims, drawings and abstract are incorporated herein by reference in its entirety.

Although various exemplary embodiments have been shown and described, the invention is not limited to the embodiments shown. Therefore, the scope of the invention is intended to be limited solely by the scope of the claims that follow.

### INDUSTRIAL APPLICABILITY

According to the preferred embodiment of the present invention, as explained above, there is provided a substrate processing apparatus in which desired gas is allowed to flow over a substrate, the substrate is heated by a lamp and a desired film is deposited on the substrate, and it is possible to restrain or prevent a deposition from being generated on a casing such as a tube which covers a lamp, and a producing method of a semiconductor device using the substrate processing apparatus.

As a result, the present invention can especially preferably be utilized for a substrate processing apparatus in which desired gas is allowed to flow over a substrate, the substrate is heated by a lamp and a desired film is deposited on the substrate, and a producing method of a semiconductor device using the substrate processing apparatus.

1. A substrate processing apparatus, comprising:
a processing chamber which provides a space for flowing desired gas and for depositing a desired film on a substrate;
a lamp unit group having at least one lamp unit which is disposed in the processing chamber and which includes a filament for heating the substrate and a lamp tube surrounding the filament;
at least first and second casings which surround the lamp unit, the first casing surrounding the lamp unit and the second casing surrounding the first casing; and
a refrigerant flowing apparatus for flowing cooling medium to a first space formed between the lamp unit and the first casing, and to a second space formed between the first casing and the second casing.

2. A substrate processing apparatus as recited in claim 1, further comprising:
a controller which controls the refrigerant flowing apparatus such that an amount of cooling medium allowed to flow into the second space is greater than an amount of cooling medium allowed to flow into the first space at least while the substrate is being processed in the processing chamber.

3. A substrate processing apparatus as recited in claim 2, wherein
the controller controls the refrigerant flowing apparatus such that the cooling medium is flowed into the second space at a constant flow rate and the cooling medium is flowed into the first space while varying a flow rate.

4. A substrate processing apparatus as recited in claim 1, further comprising:
a controller which controls amounts of cooling medium flowing into the first and second spaces such that a temperature of the first casing is lower than a temperature of the second casing at least while the substrate is being processed in the processing chamber.

5. A substrate processing apparatus as recited in claim 4, wherein
the temperature of the first casing is controlled to be in a range of 300 to 500° C.

6. A substrate processing apparatus as recited in claim 4, wherein
the temperature of the second casing is controlled to be equal to or less than 200° C.

7. A substrate processing apparatus as recited in claim 1, wherein
different cooling mediums are respectively flowed into the first space and the second space at least while the substrate is being processed in the processing chamber, and a cooling efficiency of the cooling medium flowing into the second space is higher than a cooling efficiency of the cooling medium flowing into the first space.

8. A substrate processing apparatus as recited in claim 1, further comprising:
a controller which controls the refrigerant flowing apparatus such that the flow rate of the cooling medium is greater in a process in which a temperature of the substrate located in the processing chamber is increased than in a process in which the temperature of the substrate is lowered.

9. A substrate processing apparatus as recited in claim 8, wherein
the controller controls the refrigerant flowing apparatus such that an amount of the cooling medium flowing into the second space in the process in which the temperature of the substrate is increased is the same as in the process in which the temperature of the substrate is lowered, and an amount of the cooling medium flowing into the first space in the process in which the temperature of the substrate is lowered is greater than in the process in which the temperature of the substrate is increased.

10. A producing method of a semiconductor device, comprising,
using a substrate processing apparatus, comprising:
a processing chamber which provides a space for flowing desired gas and for depositing a desired film on a substrate;
a lamp unit group having at least one lamp unit which is disposed in the processing chamber and which includes a filament for heating the substrate and a lamp tube surrounding the filament;
at least first and second casings which surround the lamp unit, the first casing surrounding the lamp unit and the second casing surrounding the first casing; and
a refrigerant flowing apparatus for flowing cooling medium to a first space formed between the lamp unit and the first casing, and to a second space formed between the first casing and the second casing,
depositing a desired film on the substrate.
